(19) United States
(12) Patent Application Publication
(10) Pub. No.: US 2007/0190247 A1
(43) Pub. Date: Aug. 16, 2007

(54) Method for forming organic light-emitting layer

(75) Inventors: Hyuk-Kyoo Jang, Seongnam-City (KR); Hyun-Chang Kim, Pyeongtaek-City (KR)

Correspondence Address: BIRCH STEWART KOLASCH & BIRCH, PO BOX 747, FALLS CHURCH, VA, 22040-0747, US

(73) Assignee: MECHARONICS CO., LTD., Pyeongtaek-City (KR)

(21) Appl. No.: 10/594,762

(22) PCT Filed: May 17, 2005
(86) PCT No.: PCT/KR05/01444

§ 371 Date: Feb. 15, 2007

(30) Foreign Application Priority Data
May 18, 2004 (KR) 10-2004-0035025
May 18, 2004 (KR) 10-2004-0035024

(51) Int. Cl. C23C 16/00

(52) U.S. Cl. 427/248.1

(57) ABSTRACT

Disclosed herein is a method for forming a light-emitting layer on an industrial scale via chemical vapor deposition or molecular layer deposition. According to the method, a metal-containing material and an 8-hydroxyquinoline derivative having stable vapor pressure characteristics are used as raw materials and are vaporized.

### TECHNICAL FIELD

The present invention relates to a method for forming an organic light-emitting layer, and more particularly to a method for forming an organic light-emitting layer on an industrial scale via chemical vapor deposition (CVD) or molecular layer deposition (MLD).

### BACKGROUND ART

Organic light-emitting layers are commonly made of Mqₙ wherein M is a metal selected from aluminum, gallium and zinc, q is 8-hydroxyquinoline derivatives, and n is an integer of 1 to 3.

Among these, Alq₃ is a compound having the structure shown in FIG. 1, and is a representative material for a light-emitting layer of an organic electroluminescent (EL) device. Conventional methods for forming a Mqₙ layer on a substrate employ thermal evaporation, which is a physical vapor deposition (PVD) process.

Thermal evaporation is a process wherein Mqₙ molecules are fed into a reaction furnace and then deposited on a substrate by heating to a high temperature. Although thermal evaporation has the advantage of easy formation of an Mqₙ layer, it has the problems that the Mqₙ layer is non-uniform and cannot be produced on a commercial scale.

### DISCLOSURE OF INVENTION

Technical Problem

Therefore, the present invention has been made in view of the above problems of thermal evaporation, and it is an object of the present invention to provide a method for forming an EL layer on an industrial scale by chemical vapor deposition or molecular layer deposition.

Technical Solution

In accordance with an aspect of the present invention for achieving the above object, there is provided a method for forming an EL layer by chemical vapor deposition, comprising the steps of:

1) placing a substrate in a reaction chamber and maintaining the inner temperature of the reaction chamber at a specific reaction temperature; and

2) simultaneously feeding a metal-containing material and an 8-hydroxyquinoline derivative into the reaction chamber and reacting the raw materials.

If necessary, the method of the present invention may further comprise the step of removing unreacted raw materials and by-products by purging after step 2).

Further, step 2) can be optionally repeated twice or more to control the thickness of the final layer.

Further, the inner reaction temperature of the reaction chamber is preferably controlled to 15˜500° C. in order to increase the reaction rate and improve the characteristics of the layer.

Further, the metal-containing material and the 8-hydroxyquinoline derivative are preferably fed into the reaction chamber for 0.1 seconds to one hour in order to increase the reaction rate and improve the characteristics of the thin layer.

In accordance with another aspect of the present invention, there is provided a method for forming a light-emitting layer by molecular layer deposition, comprising the steps of:

1) placing a substrate in a reaction chamber and maintaining the inner temperature of the reaction chamber at a specific reaction temperature;

2) feeding a metal-containing material into the reaction chamber and reacting the material with the substrate; and

3) feeding an 8-hydroxyquinoline derivative into the reaction chamber and reacting the raw materials.

If necessary, the method of the present invention may further comprise the step of removing unreacted raw materials and by-products by purging after step 2) and prior to step 3) or after step 3). The optional step is preferred in terms of shortened overall process time and improved characteristics of the final layer.

Further, steps 2) and 3) can be optionally repeated twice or more to control the thickness of the final layer.

Further, the inner reaction temperature of the reaction chamber is preferably controlled to 15˜500° C. in order to increase the reaction rate and improve the characteristics of the thin layer.

Further, the metal-containing material and the 8-hydroxyquinoline derivative are preferably fed into the reaction chamber for 0.1˜500 seconds in order to increase the reaction rate and improve the characteristics of the thin layer.

In the chemical vapor deposition or molecular layer deposition employed in the method of the present invention, a purge gas selected from the group consisting of helium (He), hydrogen (H₂), nitrogen (N₂) and argon (Ar) is supplied to the reaction chamber, and gases present in the reaction chamber are removed by suction using a vacuum pump disposed in the reaction chamber, thereby shortening the purging time and thus shortening overall process time.

The purge gas is preferably supplied at a flow rate of 10˜5,000 sccm (standard cubic centimeters per minute) for 0.1˜500 seconds.

Specific embodiments of the present invention will now be described in detail with reference to the accompanying drawings. Prior to the detailed description, it should be understood that terms and words used in the specification and claim(s) are not to be construed as having common or dictionary meanings, but should be interpreted as having meanings and concepts corresponding to the technical spirit of the present invention in view of the principle that the inventor can define proper terms in order to describe his/her invention as best possible. While embodiments described in the specification and constitutions shown in the accompanying drawings are simply the most preferred embodiments of the invention, they do not completely include the technical spirit of the invention. Therefore, it should be understood that many modifications and equivalents capable of replacing the embodiments could be made on the filing date of the application.

Advantageous Effects

According to the method of the present invention, an organic EL layer having an uniform thickness can be formed on a substrate. Therefore, the method of the present invention can be usefully applied to the formation of an light-emitting layer on a large-area substrate. In addition, the method of the present invention can be directly applied to conventional production processes of organic EL devices.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is the structural formula of Alq₃ (a representative material among Mqₙ's);

FIG. 2 is a diagram schematically showing a deposition apparatus used in a method of the present invention;

FIGS. 3a and 3b show the structure of aluminum-containing materials used in examples of the present invention;

FIG. 4 shows the structure of 8-hydroxyquinoline derivatives used in examples of the present invention;

FIGS. 5 to 6 show the respective steps of a method for forming an Alq₃ layer according to Example 1 of the present invention; and

FIGS. 7 to 14 show the respective steps of a method for forming an Alq₃ layer according to Example 2 of the present invention.

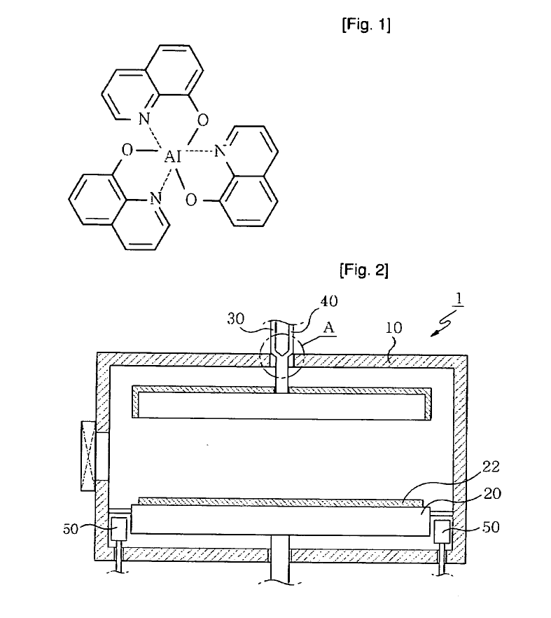

### BEST MODE FOR CARRYING OUT THE INVENTION

First, a chemical vapor deposition or a molecular layer deposition apparatus 1 employed in methods for forming Mqₙ layers according to the following Examples 1 and 2 will be explained. FIG. 2 schematically shows the structure of the deposition apparatus used in methods for forming Alq₃ layers (a representative layers among Mqₙ layers) according to Examples 1 and 2.

The apparatus is provided with a reaction chamber 10 inside which a vacuum can be formed. A susceptor 20 capable of mounting a substrate 22 on a predetermined portion of the susceptor is arranged inside the reaction chamber 10. The substrate is introduced into the reaction chamber 10 and is mounted on the susceptor 20. A thermostat (not shown in this figure) is arranged in the reaction chamber 10 to maintain the inner temperature of the reaction chamber constant.

A raw material feed pipe 30 for feeding raw materials into the reaction chamber 10 is connected to one side of the reaction chamber 10. A carrier gas supply pipe 40 for supplying a carrier gas to the reaction chamber 10 is connected adjacent to the raw material feed pipe 30. As shown in FIG. 2, it is preferred that the ends of the raw material feed pipe 30 and the carrier gas supply pipe 40 meet at an inlet port A of the reaction chamber 10 such that the raw materials and the carrier gas can be simultaneously (CVD) or sequentially (MLD) introduced into the reaction chamber 10.

One or more vacuum pumps 50 for removing gases remaining in the reaction chamber 10 by suction are connected to the reaction chamber 10. In a specific case, the reaction chamber 10 can be evacuated by the action of the vacuum pumps 50. After completion of a predetermined step, unreacted raw materials and by-products can be removed by suction using the vacuum pumps 50.

### EXAMPLE 1

In this example, a method for forming a light-emitting layer by chemical vapor deposition is described.

A substrate 22 (ITO coated glass, film or wafer) is mounted on a heating susceptor 20 arranged inside a reaction chamber 10. Thereafter, the inner temperature of the reaction chamber 10 is maintained at a temperature suitable for reaction. The reaction temperature range is preferably room temperature to 500° C. As used herein, the term “room temperature” is defined as an ambient temperature between about 15° C. and about 25° C.

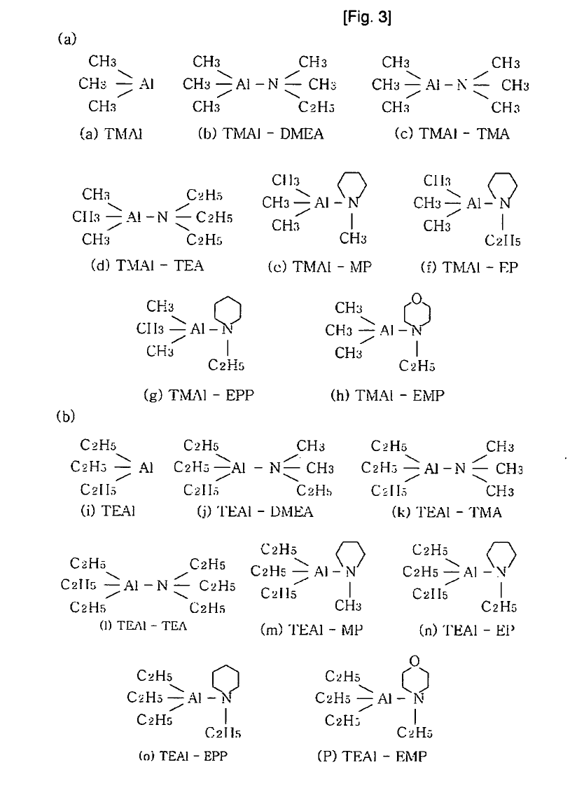

After the inner reaction temperature of the reaction chamber 10 is stabilized, a metal-containing material and an 8-hydroxyquinoline derivative are fed into the reaction chamber 10. The metal-containing material is selected from aluminum-, gallium- and zinc-containing materials. The aluminum-containing material is selected from the sixteen compounds shown in FIG. 3 and the compounds listed in Table 1 below. The aluminum-containing material is vaporized before being fed into the reaction chamber 10.

Structure of aluminum-containing materials

| General formula | Preferred structural formulae |
|---|---|
| R₁R₂R₃Al | AlMe₃, AlEt₃, AliPr₃, AliBu₃, AlBu₃, AlsBu₃, AltBu₃, |
| | AlPh₃, AlMe₂Et, AlMe₂Pr, AlMe₂iPr, AlMe₂Bu, AlMe₂iBu, |
| | AlMe₂sBu, AlMe₂tBu, AlMeEt₂, AlMePr₂, AlMeiPr₂, AlMeBu₂, |
| | AlMeiBu₂, AlMesBu₂, AlMetBu₂, AlEt₂iPr, AlEt₂Pr, AlEt₂tBu, |
| | AlEt₂Bu, AlEt₂iBu, AlEt₂sBu, Me₂AlH, Et₂AlH, iBu₂AlH, |
| | Pr₂AlH, iPr₂AlH, sBu₂AlH, tBu₂AlH |
| | Al(acac)₃, Al(tmhd)₃, Al(hfac)₃, Al(tfac)₃, Al(fod)₃ |
| | AlF₃, AlCl₃, AlBr₃, AlI₃, Al(NMe₂)₃, Al(NEt₂)₃, Al(NEtMe)₃, |
| | Al(OiPr)₂, Al(OEt)₃, Al(OtBu)₃, Al(OMe)₃, |
| | Al(methylpentoxy)₃, Al(dmamp)₃, Al(dmamb)₃ |
| | Me₂AlF, Me₂AlCl, Me₂AlBr, Me₂AlI, Et₂AlF, Et₂AlCl, Et₂AlBr, |
| | Et₂AlI, MeAlCl₂, EtAlCl₂ |
| | Et₂Alcac, Et₂AlCp, Et₂AlN₃, Me₂Alcac Me₂AlCp, Me₂AlN₃, |
| | Me₂Al(NMe₂), Et₂Al(NMe₂), Me₂Al(MeCp), Me₂Al(EtCp), |
| | Me₂Al(iPrCp), Et₂Al(MeCp), Et₂Al(EtCp), Et₂Al(iPrCp), Me₂Al |
| | (dimethylaminomethylpropoxy), Me₂Al |
| | (dimethylaminomethylbutoxy), Et₂Al(dmamp), Et₂Al(dmamb), |
| | Me₂AlOiPr, Me₂AlOtBu |
| R₁R₂R₃Al:NR₄R₅R₆ | Compounds prepared by bonding NR₄R₅R₆ to any one of the |
| | compounds R₁R₂R₃Al |
| | Me₃N, Me₂EtN, Et₃N, pyridine, iPr₂NH, iPr₃N, Me₂NCH₂CH₂NMe₂ |
| R₁R₂R₃Al:R₇N(CR₈R₉)ₙ | Compounds prepared by bonding R₇N(CR₈R₉)ₙ to any one of |
| | the compounds R₁R₂R₃Al |
| | methylaziridine, ethylaziridine, methylazetidine |
| | ethylazetidine, methylpyrrolidine, ethylpyrrolidine. |
| | methylpiperidine, ethylpiperidine, methylhexamethyleneimine |
| | ethylhexamethyleneimine, methylmorpholine, |
| | ethylmorpholine, dimethylpiperazine, diethypiperazine. |
| R₁R₂R₃Al:NR₄R₅R₆ | Compounds prepared by bonding NR₄R₅R₆ to any one of R₁R₂AlH |
| | among the compounds R₁R₂R₃Al |
| | NEtMe₂, NMe₃, NEt₃, Pyridine, NiPr₃, iPrNH, methylaziridine, |
| | ethylaziridine, methylazetidine, ethylazetidine, |
| | methylpyrrolidine, ethylpyrrolidine, methylpiperidine, |
| | ethylpiperidine, methylhexamethyleneimine, |
| | ethylhexamethyleneimine, methylmorpholine, ethylmorpholine, |
| | dimethylpiperazine, diethylpiperazine |
| II₃Al:NR₄R₅R₆ | NR₄R₅R₆ = NEtMe₂, NMe₃, NEt₃, Pyridine, NiPr₃, iPrNH, |
| | Me₂NCH₂CH₂NMe₂, methylaziridine, ethylaziridine, |
| | methylazetidine, ethylazetidine, methylpyrrolidine, |
| | ethylpyrrolidine, methylpiperidine, ethylpiperidine, |
| | methylhexamethyleneimine, ethylhexamethyleneimine, |
| | methylmorpholine, ethylmorpholine, dimethylpiperazine, |
| | diethylpiperazine |
| 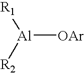 | Me₂AlOPh-4-Ph, Me₂AlOPh-2-Ph, Me₂AlOPh-3-Ph, Me₂AlO-3,3′-Me₂Ph, Me₂AlO-3,3′-tBu₂Ph, Me₂AlO-2,2′-iPr₂Ph, Me₂AlO-SiPh₃, Et₂AlOPh-4-Ph, Et₂AlOPh-2-Ph, Et₂AlOPh-3-Ph, Et₂AlO-3,3′-Me₂Ph, Et₂AlO-3,3′-tBu₂Ph, Et₂AlO-2,2′-iPr₂Ph, Et₂AlO-SiPh₃, MeEtAlOPh-4-Ph, MeEtAlOPh-2-Ph,MeEtAlOPh-3-Ph, |
| # MeEtAlO-3,3′-Me₂Ph, MeEtAlO-3,3′-tBu₂Ph, MeEtAlO-2,2′-iPr₂Ph, MeEtAlO-SiPh₃, Compounds wherein Ar is as defined above, and R₁R₂ is NMe₂, NEt₂, NEtMe, OiPr, OtBu, dmamp, dmamp or OMP (methylpropoxy) | |

Next, the gallium-containing material is selected from compounds represented by Formula 1 below and the compounds listed in Table 2.

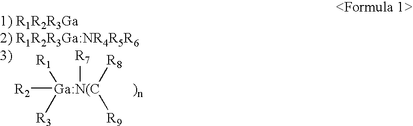

wherein R₁ to R₉, which may be the same or different, are each independently hydrogen, C_{1˜10} alkyl, alkenyl, alkynyl, aryl, cycloalkenyl, amino- or alkoxy-substituted alkyl, alkylamino, alkoxy, halogen, beta-diketone, aminoalkoxy, alkoxyalkoxy, dialkoxy, or azido; and n is an integer of 2 to 7. In the substituents R₁ to R₉, the alkyl groups may have a linear, branched, or cyclic structure. The compounds 1-2) and 1-3) are those wherein each nitrogen-containing amine compound is bonded to a gallium compound. The amine compound may be tertiary amines or a 3-, 4-, 5-, 6- or 7-membered heterocyclic amine compound. Preferred gallium-containing materials are listed in Table 2 below.

TABLE 2
Structure of gallium-containing materials

| General formula | Preferred structural formulae |
|---|---|
| R₁R₂R₃Ga | GaMe₃, GaEt₃, GaiPr₃, GaPr₃, GaiBu₃, GaBu₃, GasBu₃, GatBu₃, |
| | GaPh₃ |
| | GaMe₂Et, GaMe₂Pr, GaMe₂iPr, GaMe₂Bu, GaMe₂iBu, GaMe₂sBu, |
| | GaMe₂tBu, GaMeEt₂, GaMePr₂, GaMeiPr₂, GaMeBu₂, GaMeiBu₂, |
| | GaMesBu₂, GaMetBu₂, GaEt₂iPr, GaEt₂Pr, GaEt₂tBu, GaEt₂Bu, |
| | GaEt₂iBu, GaEt₂sBu |
| | Ga(acac)₃, Ga(tmhd)₃, Ga(hfac)₃, Ga(tfac)₃, Ga(fod)₃ |
| | GaF₃, GaCl₃, GaBr₃, GaI₃, Ga(NMe₂)₃, Ga(NEt₂)₃, Ga(NEtMe)₃, |
| | Ga(OiPr)₃, Ga(OEt)₃, Ga(OtBu)₃, Ga(OMe)₃, |
| | Ga(methylpentoxy)₃ |
| | Me₂GaF, Me₂GaCl, Me₂GaBr, Me₂GaI, Et₂GaF, Et₂GaCl, Et₂GaBr, |
| | Et₂GaI, MeGaCl₂, EtGaCl₂ |
| | Et₂Gacac, Et₂GaCp, Et₂GaN₃, Me₂Gacac, Me₂GaCp, Me₂GaN₃, |
| | Me₂Ga(NMe₂), Et₂Ga(Me₂), Me₂Ga(MeCp), Me₂Ga(EtCp), |
| | Me₂Ga(iPrCp), Et₂Ga(MeCp), Et₂Ga(EtCp), Et₂Ga(iPrCp), |
| | Me₂Ga(dimethylaminomethylpropoxy), Me₂Ga |
| | (dimethylaminomethylbutoxy), Et₂Ga(dmamp), Et₂Ga(dmamb) |
| R₁R₂R₃Ga:NR₄R₅R₆ | Compounds prepared by bonding NR₄R₅R₆ to any one of the |
| | compounds R₁R₂R₃Ga |
| | Me₃N, Me₂EtN, Et₃N, pyridine, iPr₂NH, NiPr₃, Me₂NCH₂CH₂NMe₂ |
| R₁R₂R₃Ga:R₇N(CR₈R₉)ₙ | Compounds prepared by bonding R₇N(CR₈R₉)ₙ to any one of |
| | the compounds R₁R₂R₃Ga |
| | methylaziridine, ethylaziridine, methylazetidine, |
| | ethylazetidine, methylpyrrolidine, ethylpyrrolidine, |
| | methylpiperidine, ethylpiperidine, |
| | methylhexamethyleneimine, ethylhexamethyleneimine, |
| | methylmorpholine, ethylmorpholine, dimethylpiperazine, |
| | diethylpiperazine |

Next, the zinc-containing material is preferably selected from compounds represented by Formula 2 below and the compounds listed in Table 3.
1)R₁R₂Zn
2) R₁R₂Zn:NR₃R₄R₅
3) R₁R₂Zn:R₆N(CR₇R₈)ₙ <Formula 2>

wherein R₁ to R₈, which may be the same or different, are each independently hydrogen, C_{1˜10} alkyl, alkenyl, alkynyl, aryl, cycloalkenyl, amino- or alkoxy-substituted alkyl, alkylamino, alkoxy, halogen, beta-diketone, aminoalkoxy, alkoxyalkoxy, dialkoxy, or azido; and n is an integer of 2 to 7. In the substituents R₁ to R₈, the alkyl groups may have a linear, branched, or cyclic structure. The compounds 2-2) and 2-3) are those wherein each nitrogen-containing amine compound is bonded to a zinc compound. The amine compound may be tertiary amines or a 3-, 4-, 5-, 6- or 7-membered heterocyclic amine compound. Preferred zinc-containing materials are listed in Table 3 below.

TABLE 3
Structure of zinc-containing materials

| General formula | Preferred structural formulae |
|---|---|
| R₁R₂Zn | ZnMe₂, ZnEt₂, ZnPr₂, ZniPr₂, ZnBu₂, ZniBu₂, ZnsBu₂, ZntBu₂, |
| | ZnPh₂, ZnMeEt, ZnMePr, ZnMeiPr, ZnMeBu, ZnMeiBu, ZnMesBu, |
| | ZnMetBu, ZnEtPr, ZnEtiPr, ZnEtBu, ZnEtiBu, ZnEtsBu, |
| | ZnEttBu, ZnPriPr, ZnPrBu, ZnPriBu, ZnPrsBu, ZnPrtBu, |
| | Zn(acac)₂, Zn(tmhd)₂, Zn(hfac)₂, Zn(tfac)₂, Zn(fod)₂ |
| | ZnF₂, ZnCl₂, ZnBr₂, ZnI₂, Zn(NMe₂)₂, Zn(NEt₂)₂, Zn(NEtMe)₂, |
| | Zn(OiPr)₂, Zn(OEt)₂, Zn(OtBu)₂, Zn(OMe)₂, Zn(methylpentoxy)₂ |
| | MeZnF, MeZnCl, MeZnBr, MeZnI, EtZnF, EtZnCl, EtZnBr, |
| | EtZnI, |
| | EtZnacac, EtZnCp, EtZnN₃, MeZnacac, MeZnCp, MeZnN₃, |
| | McZn(NMc₂), EtZn(NMc₂), McZn(McCp), McZn(EtCp), |
| | MeZn(iPrCp), EtZn(MeCp), EtZn(EtCp), EtZn(iPrCp), |
| | MeZn(dimethylaminomethylpropoxy), |
| | MeZn(dimethylaminomethylbutoxy), EtZn(dmamp), EtZn(dmamb), |
| | MeZnOiPr, MeZnOtBu, MeZnOPr, MeZnOBu, MeZnOsBu, EtZnOiPr, |
| | EtZnOtBu, EtZnOPr, EtZnOBu, EtZnOsBu, |
| R₁R₂Zn:NR₃R₄R₅ | Compounds prepared by bonding NR₃R₄R₅ to any one of the |
| | compounds R₁R₂Zn |
| | Me₃N, Me₂EtN, Et₃N, pyridine, iPr₂NH, NiPr₃, Me₂NCH₂CH₂NMe₂ |
| R₁R₂Zn:R₆N(CR₇R₈)ₙ | Compounds prepared by bonding R₆N(CR₇R₈)ₙ to any one of the |
| | compounds R₁R₂Zn |
| | methylaziridine, ethylaziridine, methylazetidine, |
| | ethylazetidine, methylpyrrolidine, ethylpyrrolidine, |
| | methylpiperidine, ethylpiperidine, |
| | methylhexamethyleneimine, ethylhexamethyleneimine, |
| | methylmorpholine, ethylmorpholine, dimethylpiperazine, |
| | diethylpiperazine |

The 8-hydroxyquinoline derivative is selected from compounds having the structures shown in FIG. 4. Since the metal-containing material and the 8-hydroxyquinoline derivative have good vaporization characteristics, they can be easily used for chemical vapor deposition. In addition, since the raw materials show relatively stable vapor pressure characteristics, they can be produced on a commercial scale.

For the CVD process, The metal-containing material and the 8-hydroxyquinoline derivative are fed into the reaction chamber 10 simultaneously with or without a carrier gas for 0.1 seconds to one hour.

In this example, the metal-containing material and the 8-hydroxyquinoline derivative are fed into the reaction chamber 10 through the raw materials feed pipe 30 and pipe 40, as shown in FIG. 2. Normally, it is used by a showerhead for the feed and the purge of the raw materials (not shown in FIG. 2). The raw materials introduced through the respective pipes meet at an inlet port A of the reaction chamber 10. The simultaneous introduction of the carrier gas and the raw materials advantageously prevents the formation of particles due to reaction of the raw materials inside the raw material feed pipe. The flow rate of the carrier gas is preferably controlled to 1˜5,000 sccm.

The metal-containing material is reacted with the 8-hydroxyquinoline derivative in the reaction chamber 10 to form an Mqₙ layer on the substrate 22. After formation of the Mqₙ thin layer on the substrate 22, a process for removing unreacted raw materials and by-products formed after the reaction is necessary. Considering the fact that raw materials are generally used in larger amounts than those needed for a reaction between the raw materials, a purging process is required to remove unreacted materials and by-products remaining in the reaction chamber 10 for subsequent reactions.

In this example, the purging process is carried out in accordance with the following two procedures. First, unreacted raw materials and by-products present in the reaction chamber 10 are removed using vacuum pumps 50 connected to the reaction chamber 10. Specifically, the vacuum pumps 50 absorb all gases present in the reaction chamber 10 and discharge the gases to the atmosphere, to remove impurities present in the reaction chamber 10. Disadvantages of this purging process are that the process is time-consuming and the removal of the unreacted materials and by-products is insufficient.

Accordingly, it is preferred that gases remaining in the reaction chamber 10 are removed by suction using the vacuum pumps 50 while a purge gas is supplied to the reaction chamber 10 through the carrier gas supply pipe 30 and pipe 40. That is, the unreacted raw materials and by-products are discharged to the atmosphere through the vacuum pumps 50 while the purge gas is supplied to the reaction chamber 10. The purge gas is preferably selected from helium (He), hydrogen (H₂), nitrogen (N₂), and argon (Ar). The purge gas is preferably supplied to the reaction chamber at a flow rate of 1˜5,000 sccm for 1˜60 minutes.

When the unreacted raw materials and by-products are completely removed from the reaction chamber 10, the method for forming an Mqₙ layer by chemical vapor deposition according to the embodiment of the present invention is completed. If necessary, the purging process can be repeated in such a manner that the Mqₙ thin layer formed on the substrate has a desired thickness.

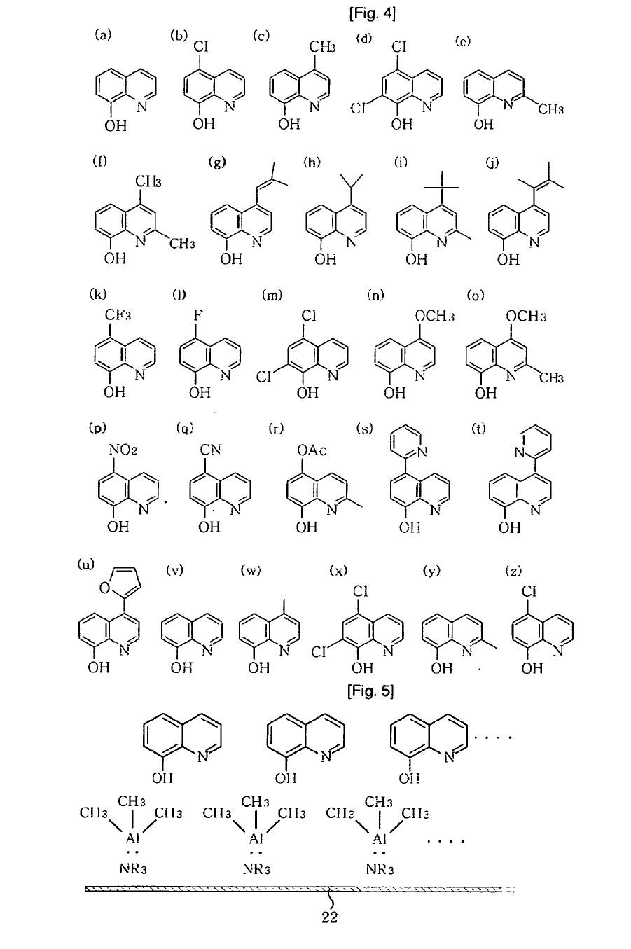

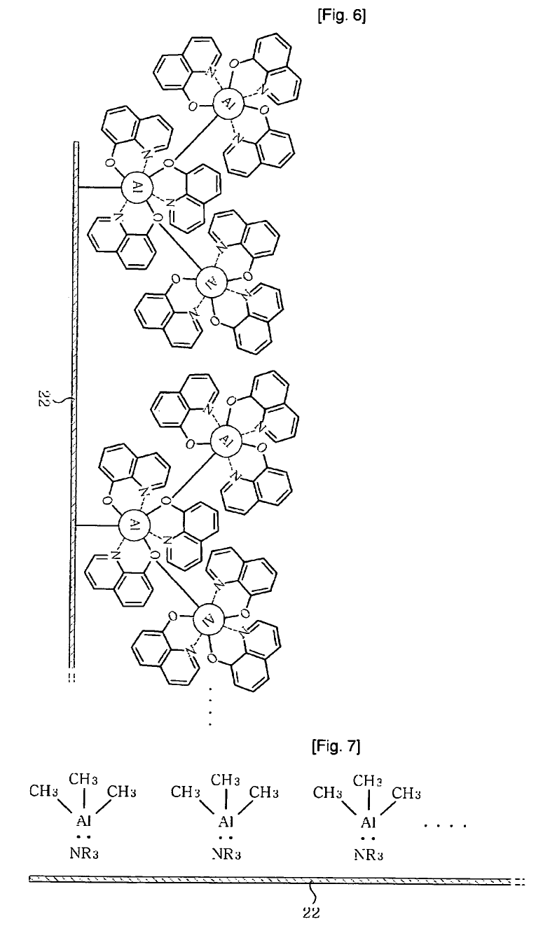

Referring to FIGS. 5 and 6, deposition of Alq₃ on a substrate will be explained in more detail.

As shown in FIG. 5, an aluminum-containing material and an 8-hydroxyquinoline derivative are fed into a reaction chamber 10 in which a substrate 22 is located. As shown in FIG. 6, the aluminum-containing material is reacted with the 8-hydroxyquinoline derivative while maintaining the reaction temperature constant to form an Alq₃ layer on the substrate. After formation of the Alq₃ layer on the substrate 22, unreacted raw materials and by-products are removed from the reaction chamber by purging.

A desired thickness can be obtained by controlling flow rates, temperatures, deposition time etc.

### EXAMPLE 2

In this example, a method for forming an Alq₃ layer by molecular layer deposition is described.

A substrate 22 is mounted on a susceptor 20 arranged inside a reaction chamber 10. Thereafter, the inner temperature of the reaction chamber 10 is maintained at a temperature suitable for reaction. The reaction temperature range is preferably room temperature to 500° C. As used herein, the term “room temperature” is defined as an ambient temperature between about 15° C. and about 25° C.

After the inner reaction temperature of the reaction chamber 10 is stabilized, an aluminum-containing material is fed into the reaction chamber 10. The aluminum-containing material is selected from the sixteen compounds having the structures shown in FIG. 3 and some compounds are listed in Table 1. The aluminum-containing material is vaporized before being fed into the reaction chamber 10. Since the aluminum-containing material has good vaporization characteristics, they can be easily used for molecular layer deposition. In addition, since the aluminum-containing material shows relatively stable vapor pressure characteristics, it can be produced on a commercial scale. The aluminum-containing material is preferably fed for 0.1˜500 seconds.

The aluminum-containing material may be fed alone or in combination with a carrier gas into the reaction chamber 10. In this example, the aluminum-containing material is fed into the reaction chamber 10 through a raw material feed pipe 30 while the carrier gas is supplied to the reaction chamber 10 through a carrier gas supply pipe 40, as shown in FIG. 2. Normally, it is used by a showerhead for the feed and the purge of the raw materials (not shown in FIG. 2). The aluminum-containing material and the carrier gas introduced through the respective pipes meet at an inlet port A of the reaction chamber 10. The simultaneous introduction of the carrier gas and the aluminum-containing material advantageously prevents the formation of particles due to reaction of the raw material inside the raw material feed pipe. The flow rate of the carrier gas is preferably controlled to 1˜5,000 sccm.

The aluminum-containing material is fed into the reaction chamber 10 to form an atomic or molecular layer of the aluminum-containing material on the substrate 22. After formation of the atomic or molecular layer on the substrate 22, a process for removing unreacted raw materials and by-products formed after the reaction is necessary. Considering the fact that raw materials are generally used in larger amounts than those needed for a reaction between the raw materials, a purging process is required to remove unreacted materials and by-products remaining in the reaction chamber 10 for subsequent reactions.

In this example, the purging process is carried out in accordance with the following two procedures. First, unreacted reacted materials and by-products present in the reaction chamber 10 are removed using vacuum pumps 50 connected to the reaction chamber 10. Specifically, the vacuum pumps 50 absorb all gases present in the reaction chamber 10 and discharge the gases to the atmosphere, to remove impurities present in the reaction chamber 10. Disadvantages of this purging process are that the process is time-consuming and the removal of the unreacted materials and by-products is insufficient.

Accordingly, it is preferred that gases remaining in the reaction chamber 10 are removed by suction using the vacuum pumps 50 while a purge gas is supplied to the reaction chamber 10 through the carrier gas supply 30 and pipe 40. That is, the unreacted raw materials and by-products are discharged to the atmosphere through the vacuum pumps 50 while the purge gas is supplied to the reaction chamber 10. The purge gas is preferably selected from helium (He), hydrogen (H₂), nitrogen (N₂), and argon (Ar). The purge gas is preferably supplied to the reaction chamber at a flow rate of 1˜5,000 sccm for 0.1˜1,000 seconds.

After removal of unreacted aluminum-containing material and reaction by-products from the reaction chamber 10, an 8-hydroxyquinoline derivative is fed into the reaction chamber 10 through the raw material feed pipe 40. Like the aluminum-containing material, the 8-hydroxyquinoline derivative is vaporized before being fed into the reaction chamber 10. The 8-hydroxyquinoline derivative may be fed alone, but is preferably fed into the reaction chamber 10 in combination with or without the carrier gas. The feeding conditions of the 8-hydroxyquinoline derivative are preferably the same as those of the aluminum-containing material. The 8-hydroxyquinoline derivative used in this example is selected from compounds having the structures shown in FIG. 4. Namely, the 8-hydroxyquinoline derivative is selected from 8-hydroxyquinoline, 5-chloro-8-hydroxyquinoline, 4-methyl-8-hydroxyquinoline, and 5,7-dichloro-8-hydroxyquinoline etc.

As described above, the 8-hydroxyquinoline derivative fed into the reaction chamber 10 undergoes a surface reaction with the atomic or molecular layer of the aluminum-containing material, which is formed on the substrate 22, to form an Alq₃ layer. After completion of the reaction, a purging process is again carried out in the same manner under the same conditions as the previous purging process to remove unreacted raw materials and reaction by-products.

The above procedure (one cycle) is repeated until the Alq₃ layer is formed to a desired thickness on the substrate.

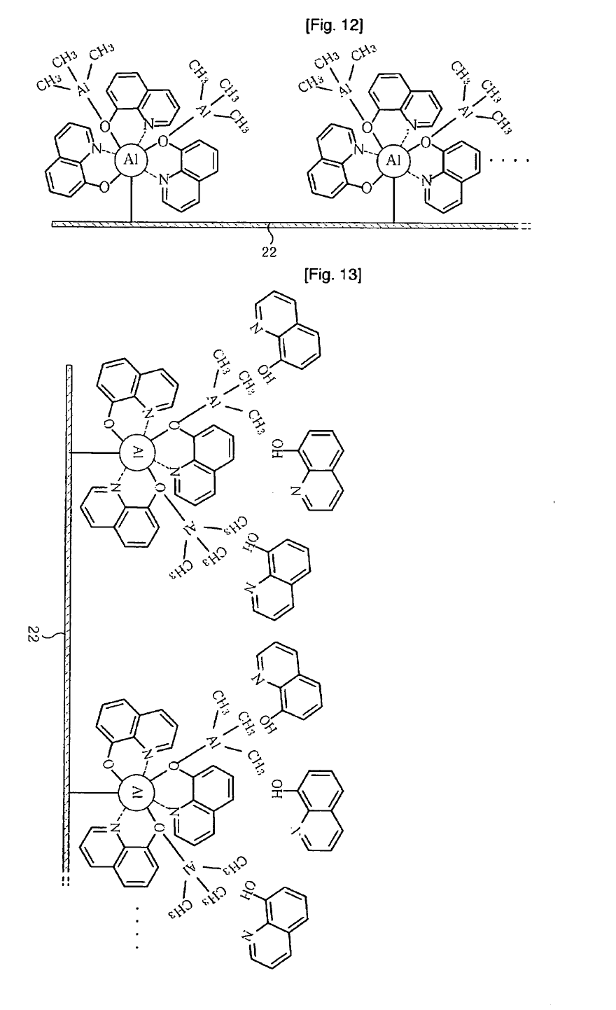

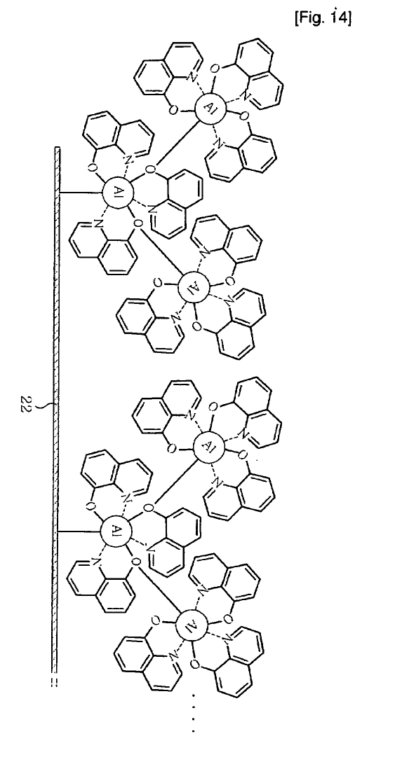

From FIGS. 7 to 14, deposition of Alq₃ on a substrate by using MLD will be explained in more detail.

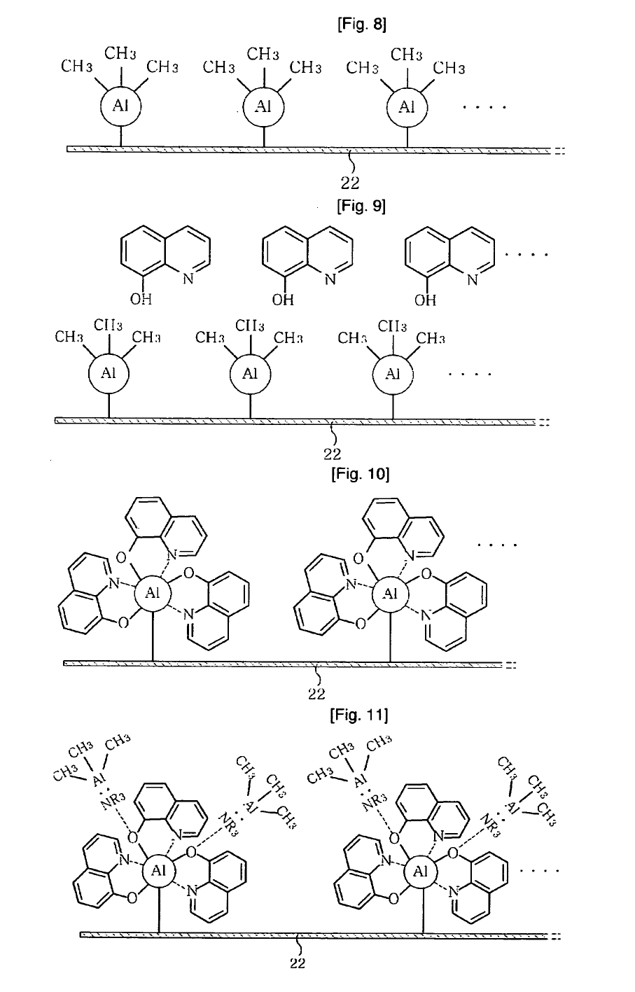

As shown in FIG. 7, an aluminum-containing material is fed into a reaction chamber 10 in which a substrate 22 is located. As shown in FIG. 8, the aluminum-containing material is reacted with the substrate while maintaining the reaction temperature constant to form an atomic or molecular layer of the aluminum-containing material on the substrate 22. After formation of the layer of the aluminum-containing material on the substrate 22, unreacted raw materials is removed from the reaction chamber by purging. As shown in FIG. 9, a quinoline derivative is fed into the reaction chamber 10. As shown in FIG. 10, the quinoline derivative is reacted with the layer of the aluminum-containing material to form an Alq₃ layer on the substrate 22. Finally, unreacted quinoline derivative and by-products are purged.

This procedure is repeated until the Alq₃ thin layer reaches a desired thickness (FIGS. 11˜14).

1. A method for forming a light-emitting layer by atomic or molecular layer deposition, comprising the steps of:
1) placing a substrate in a reaction chamber and maintaining the inner temperature of the reaction chamber at a specific reaction temperature;
2) feeding a metal-containing material into the reaction chamber and reacting the material with the substrate; and
3) feeding an 8-hydroxyquinoline derivative into the reaction chamber and reacting the raw materials.

2. The method according to claim 1, further comprising the step of removing unreacted raw materials and by-products by first purging after step 2) and prior to step 3).

3. The method according to claim 1, further comprising the step of removing unreacted raw materials and by-products by second purging after step 3).

4. The method according to claim 1, wherein steps 2) and 3) are repeated twice or more.

5. The method according to claim 1, wherein the metal-containing material and the 8-hydroxyquinoline derivative are fed into the reaction chamber for 0. 1˜500 seconds.

6. The method according to claim 2, wherein the first purging is carried out by absorbing and removing unreacted raw materials and by-products using a vacuum pump disposed in the reaction chamber.

7. The method according to claim 2, wherein the first purging is carried out by supplying a purge gas selected from the group consisting of helium (He), hydrogen (H₂), nitrogen (N₂) and argon (Ar) to the reaction chamber, and absorbing and removing gases present in the reaction chamber using a vacuum pump disposed in the reaction chamber.

8. The method according to claim 7, wherein the purge gas is supplied at a flow rate of 1˜5,000 sccm for 0.1˜500 seconds.

9. The method according to claim 3, wherein the second purging is carried out by absorbing and removing unreacted raw materials and by-products using a vacuum pump disposed in the reaction chamber.

10. The method according to claim 3, wherein the second purging is carried out by supplying a purge gas selected from the group consisting of helium (He), hydrogen (H₂), nitrogen (N₂) and argon (Ar) to the reaction chamber, and absorbing and removing gases present in the reaction chamber using a vacuum pump disposed in the reaction chamber.

11. The method according to claim 10, wherein the purge gas is supplied at a flow rate of 1˜5,000 sccm for 0.1˜500 seconds.

12. A method for forming a light-emitting layer by chemical vapor deposition, comprising the steps of:
1) placing a substrate in a reaction chamber and maintaining the inner temperature of the reaction chamber at a specific reaction temperature; and
2) simultaneously feeding a metal-containing material and an 8-hydroxyquinoline derivative into the reaction chamber with or without carrier gas and reacting the raw materials.

13. The method according to claim 12, further comprising the step of removing unreacted raw materials and by-products by purging after step 2).

14. The method according to claim 12, wherein step 2) is repeated twice or more.

15. The method according to claim 12, wherein the metal-containing material and the 8-hydroxyquinoline derivative are fed into the reaction chamber for 1 seconds to one hour.

16. The method according to claim 13, wherein the purging is carried out by absorbing and removing unreacted raw materials and by-products using a vacuum pump disposed in the reaction chamber.

17. The method according to claim 12 and 13, wherein the carrier or the purge is carried out by supplying a gas selected from the group consisting of helium (He), hydrogen (H₂), nitrogen (N₂) and argon (Ar) to the reaction chamber, and absorbing and removing gases present in the reaction chamber using a vacuum pump disposed in the reaction chamber.

18. The method according to claim 17, wherein the carrier gas or the purge gas is supplied at a flow rate of 1˜5,000 sccm for 1˜60 minutes.

19. The method according to claim 1 or 12, wherein the reaction temperature is between 15° C. and 500° C.

20. The method according to claim 1 or 12, wherein the metal-containing material is selected from aluminum-, gallium- and zinc-containing materials.

21. The method according to claim 20, wherein the aluminum-containing material is selected from the group consisting of:
trimethylaluminum (TMAl);
trimethylaluminum-dimethylethylamine (TMAl-DMEA);
trimethylaluminum-trimethylamine (TMAl-TMA);
trimethylaluminum-triethylamine (TMAl-TEA);
trimethylaluminum-methylpyrrolidine (TMAl-MP);
trimethylaluminum-ethylpyrrolidine (TMAl-EP);
trimethylaluminum-ethylpiperidine (TMAl-EPP);
trimethylaluminum-ethylmorpholine (TMAl-EMP);
triethylaluminum (TEAl);
triethylaluminum-dimethylethylamine (TEAl-DMEA);
triethylaluminum-trimethylamine (TEAl-TMA);
triethylaluminum-triethylamine (TEAl-TEA);
triethylaluminum-methylpyrrolidine (TEAl-MP);
triethylaluminum-ethylpyrrolidine (TEAl-EP);
triethylaluminum-ethylpiperidine (TEAl-EPP); and
triethylaluminum-ethylmorpholine (TEAl-EMP).

22. The method according to claim 20, wherein the aluminum-containing material is selected from the compounds listed in Table 1.

23. The method according to claim 20, wherein the gallium-containing material is selected from the compounds listed in Table 2.

24. The method according to claim 20, wherein the zinc-containing material is selected from the compounds listed in Table 3.

25. The method according to claim 1 or 12, wherein the 8-hydroxyquinoline derivative is selected from the compounds listed in FIG. 4.

26. The method according to claim 1 or 12, wherein the metal-containing material and the 8-hydroxyquinoline derivative are vaporized before being fed into the reaction chamber.
